(19) United States
(12) Patent Application Publication
(10) Pub. No.: US 2018/0275315 A1
(43) Pub. Date: Sep. 27, 2018

(54) FILTER

(71) Applicants: Platinum Optics Technology(Suzhou)Inc., Jiangsu (CN); Platinum Optics Technology Inc., Taoyuan City (TW)

(72) Inventors: Chun-Cheng HSIEH, Taoyuan City (TW); Chun-Yao OU, Taoyuan City (TW); Chung-Han LU, Taoyuan City (TW)

(21) Appl. No.: 15/662,747

(22) Filed: Jul. 28, 2017

(30) Foreign Application Priority Data
Mar. 27, 2017 (CN) 201710190154.5

(51) Int. Cl. G02B 1/04; G02B 5/20; G02B 5/22; C08K 5/3417; H01L 27/146

(52) U.S. Cl. CPC G02B 1/04; G02B 5/208; G02B 5/22; H01L 27/14625; H01L 27/14618; H01L 27/14621; C08K 5/3417

(57) ABSTRACT

The present disclosure is related to a filter, which includes a near infrared light filtering substrate, having a near infrared light absorbing dye; an absorbing layer, having a near infrared light absorbing dye and an ultraviolet light absorbing dye, and formed on one surface of the near infrared light filtering substrate; a first multi-layer film, formed on the absorbing layer; and a second multi-layer film, formed on the other surface of the near infrared light filtering substrate.

### CROSS REFERENCE TO RELATED APPLICATION

This application claims the priority benefit of China Patent Application Serial Number 201710190154.5, filed on Mar. 27, 2017, the full disclosure of which is incorporated herein by reference.

### BACKGROUND

### Technical Field

The present disclosure generally relates to a filter and, more particularly, to a filter for an image capturing device.

### Related Art

In the digital era, mobile devices such as cameras or mobile phones use a charge-coupled device (CCD) or a complementary metal-oxide semiconductor (CMOS) to convert an image to an electronic digital signal. The CCD or CMOS may sense visible light and infrared simultaneously. However, the infrared may interfere the normal images, affect the color of normal images, and generate problems such as heat and noise. Specifically, a wavelength of a sensing range of an image sensor to the light is about 350 nm to 1200 nm, and thus it may capture an infrared light and an ultraviolet light. In order to avoid the image presentation from affecting by the infrared light and the ultraviolet light, a filter is disposed in front of the image sensor to block the infrared light and the ultraviolet light to enter the image sensor. Therefore, the above image problem is avoided and the sensing range of the visible light is modified to reduce phenomenon of color shift of the image. On the other hand, in order to solve the problem of the color shift due to the large-angled incident light received by the CCD or CMOS in the thin mobile devices, the transmittance of the filter is required to have more rapid change between the wavelength of 630 to 700 nm.

For the filter of the prior art applied in the image capturing device, the transparent resin is used as a base material for the filter. However, the filter of the prior art does not adequately shield the infrared light and the ultraviolet light.

Generally, in order to reduce the cost and reduce the yield decline due to various manufacturing process, it is desirable to reduce the number of the film layers of the filter with the infrared light cutoff function as less as possible. However, reducing the number of the layer of the filter may affect the spectrum property, and it would be difficult to achieve the ideal infrared and ultraviolet cutoff performance.

### SUMMARY

The present disclosure is to provide a filter, which may reduce color shift phenomenon caused by the incident light emitting at different incident angles and maintain the transmittance of a visible light. In other aspects, the filter provided by the present disclosure may at least improve the transmittance of the visible light between the wavelength of 600 nm to 700 nm and may efficiently absorb a near infrared light and an ultraviolet light.

The present disclosure provides a filter, which includes a near infrared light filtering substrate having a near infrared light absorbing dye; an absorbing layer having a near infrared light absorbing dye and an ultraviolet light absorbing dye, and formed on one surface of the near infrared light filtering substrate; a first multi-layer film, formed on the absorbing layer; and a second multi-layer film, formed on the other surface of the near infrared light filtering substrate. The near infrared light absorbing dyes of the near infrared light filtering substrate and the absorbing layer in the filter of the present disclosure may generate different spectrum property, thereby adjusting and controlling a spectrum pattern required by the filter.

It should be understood, however, that this summary may not contain all aspects and embodiments of the present invention, that this summary is not meant to be limiting or restrictive in any manner, and that the invention as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic view of a filter according to an embodiment of the present disclosure;

FIG. 2 is a manufacturing flowchart of a filter according to an embodiment of the present disclosure; and

FIG. 3 is a schematic view of a spectral transmission curve of a filter according to an embodiment of the present disclosure.

### DETAILED DESCRIPTION OF THE EMBODIMENTS

The present disclosure will now be described more fully hereinafter with reference to the accompanying drawings, in which exemplary embodiments of the invention are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

In the following embodiment, the same reference numerals are used to refer to the same or similar elements throughout.

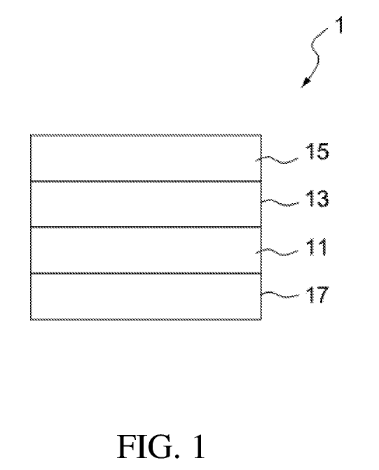

Please refer to FIG. 1, which is a schematic view of a filter 1 according to an embodiment of the present disclosure. As shown in FIG. 1, the present disclosure provides a filter 1, and the filter 1 includes a near infrared light filtering substrate 11, an absorbing layer 13, a first multi-layer film 15 and a second multi-layer film 17. The near infrared light filtering substrate 11 has a near infrared light absorbing dye. The absorbing layer 13 includes a near infrared light absorbing dye and an ultraviolet light absorbing dye, and is formed on one surface of the near infrared light filtering substrate 11. In one embodiment, the near infrared light absorbing dye may usually be at least one of squarylium compounds, phthalocyanines, naphthalocyanines and cyanine compounds. The near infrared light absorbing dye may absorb the light having the wavelength between 630 nm to 800 nm. The ultraviolet light absorbing dye may usually be at least one of azomethine-based compounds, indole-based compounds, benzotriazole-based compounds and triazine-based compounds. The ultraviolet light absorbing dye may absorb the light having the wavelength between 300 nm to 400 nm. The first multi-layer film 15 formed on the absorbing layer 13. The second multi-layer film 17 is formed on the other surface of the near infrared light filtering substrate 11.

FIG. 1 further illustrates that the near infrared light filtering substrate 11 and the absorbing layer 13 are two-layered structure, and the absorbing layer 13 is formed on the near infrared light filtering substrate 11. The near infrared light filtering substrate 11 is formed by mixing a resin and a near infrared light absorbing dye, and the absorbing layer 13 is formed by mixing a resin, a near infrared light absorbing dye and an ultraviolet light dye. The near infrared light filtering substrate 11 is formed through a melt forming, an injection molding, a casting molding or a blow molding, and a thickness thereof is between 90 μm to 200 μm. In one embodiment, the resin of the near infrared light filtering substrate 11 includes at least one of polycarbonate, polystyrene, propylene-styrene copolymer, polymethyl methacrylate, polyvinylchloride, low density polyethylene, ethylene-vinyl acetate and cyclic polyolefin resin. The resin of the absorbing layer 13 includes a thermoplastic resin (such as Polyester resin, Acrylic resin, Polycarbonate resin, Polyamide resin, Alkyd resin and so on) or a thermosetting resin (such as Epoxy resin or Thermosetting Acrylic resin). The absorbing layer 13 is formed by averagely coating the mixed material of the absorbing layer 13 on the near infrared light filtering substrate 11 through a spin coating method. For example, the mixed material of the absorbing layer 13 is coated on the near infrared light filtering substrate 11 through a spin coating method, wherein the spinning speed is 1100 rpm, and the method maintains about one hour under an environment condition between 100° C. to 130° C., such that the absorbing layer 13 is formed on the near infrared light filtering substrate 11. A good adhesion exists between the absorbing layer 13 and the near infrared light filtering substrate 11, such that it is not easy for the absorbing layer 13 to strip from the near infrared light filtering substrate 11 due to an outer environment change, such as temperature, pressure. In one embodiment, a thickness of absorbing layer 13 formed by the above method is between 2.5 μm to 3.5 μm, and in one further embodiment, a thickness of the absorbing layer 13 is 3 μm. The absorbing layer 13 may absorb the light having a wavelength between 350 nm to 420 nm or between 630 nm to 800 nm. The absorbing layer 13 may also be coated on the near infrared light filtering substrate 11 through a spray coating method, a curtain coating method, a gravure coating method, an air knife coating method, a blade coating method or a reverse gravure coating method.

The first multi-layer film 15 is formed on the absorbing layer 13 through an evaporation process. The second multi-layer film 17 is formed on the other surface of the near infrared light filtering substrate 11 through the evaporation process and is opposite to the absorbing layer 13. In one embodiment, the first multi-layer film 15 and the second multi-layer film 17 may be separately formed on the absorbing layer 13 and the near infrared light filtering substrate 11 through a vapor film forming method (such as one or the combination of Sputtering, Electron Beam Evaporation, Ion Beam Evaporation Chemical Vapor Deposition). In one embodiment, the first multi-layer film 15 and the second multi-layer film 17 is formed through an electron gun evaporation with an ion-assisted deposition. In one embodiment, the first multi-layer film 15 and the second multi-layer 17 separately use an alternate evaporation method to obtain a multi-layer structure including TiO₂ and SiO₂. In one embodiment, the thicknesses of the first multi-layer film 15 and the second multi-layer film 17 are 10 nm to 500 nm, and in one further embodiment 60 nm to 150 nm. The first multi-layer film 15 and the second multi-layer film 17 is used for absorbing light with the wavelength range between 700 nm to 1200 nm.

The filter 1 showed in FIG. 1 may generate different spectrum property in different mediums through the near infrared light absorbing dye, so as to adjust and control a spectrum pattern required by the filter 1. In one embodiment, the ratio of the mass concentration (mole/volume) of the near infrared light absorbing dye contained in the near infrared light filtering substrate 11 and the absorbing layer 13 is different, as shown in FIG. 1. When the ratio of mass concentration of the near infrared light absorbing dye contained in the near infrared light filtering substrate to mass concentration of the near infrared light absorbing dye contained in the absorbing layer is 1:0.03, the desired performance may be presented. Additionally, when the ratio is 1:0.03, in the wavelength range between 430 to 580 nm, the average transmittance of the filter 1 may be maintained above 88%. In the wavelength range between 590 to 630 nm, the average transmittance of the filter 1 may be maintained above 60%. In the wavelength range between 700 to 720 nm, the average transmittance of the filter 1 may be lowered below 2%. In the infrared region, a difference between a wavelength of the filter 1 with 40% transmittance and a wavelength of the filter 1 with 20% transmittance is 27 nm, and therefore it has smaller difference compared to the other ratios. The visible light may effectively transmit the filter 1 and the near infrared light may be effectively absorbed at the aforementioned composition ratio.

TABLE 1

| | ratio of mass concentration of the near infrared light | | | | | | |
|---|---|---|---|---|---|---|---|
| | absorbing dye contained in the near infrared light filtering | | | | | | |
| | substrate to mass concentration of the near infrared light | | | | | | |
| | absorbing dye contained in the absorbing layer | | | | | | |
| | 1:0 | 1:0.005 | 1:0.01 | 1:0.02 | 1:0.03 | 1:0.05 | 1:0.1 |
| average transmittance | 89.7 | 89.4 | 88.9 | 89.3 | 89.1 | 85.3 | 82.4 |
| (%) at wavelength | | | | | | | |
| between 430 and | | | | | | | |
| 580 nm | | | | | | | |
| average transmittance | 67.3 | 65.4 | 63.8 | 63.6 | 63.2 | 60.5 | 57.6 |
| (%) at wavelength | | | | | | | |
| between 590 and | | | | | | | |
| 630 nm | | | | | | | |
| average transmittance | 8.2 | 7.07 | 3.4 | 2.3 | 1.4 | 1.2 | 1.3 |
| (%) at wavelength | | | | | | | |
| between 700 and | | | | | | | |
| 720 nm | | | | | | | |
| In infrared region and | 640 | 638 | 641 | 635 | 637 | 628 | 621 |
| wavelength with 40% | | | | | | | |
| transmittance (nm) | | | | | | | |
| (λ₄₀ [nm]) | | | | | | | |
| In infrared region and | 687 | 678 | 674 | 665 | 664 | 656 | 650 |
| wavelength with 20% | | | | | | | |
| transmittance (nm) | | | | | | | |
| (λ₂₀ [nm]) | | | | | | | |
| difference between | 47 | 40 | 33 | 30 | 27 | 28 | 29 |
| λ₂₀ [nm] and λ₄₀ [nm] | | | | | | | |

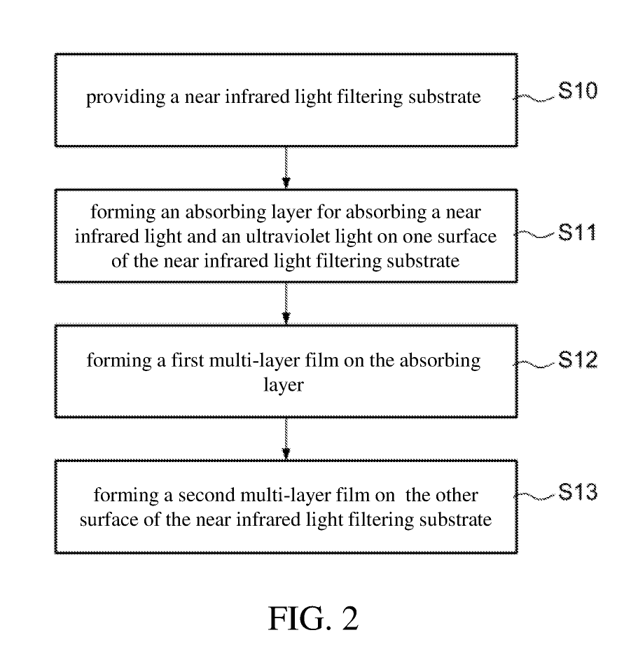

Please refer to FIG. 2, which is a manufacturing flowchart of a filter 1 according to an embodiment of the present disclosure. As shown in FIG. 2, the manufacturing method of the filter 1 of the present disclosure firstly performs step S10. The method involves providing a near infrared light filtering substrate 11. Then Step S11 is performed, and the method involves forming an absorbing layer 13 for absorbing a near infrared light and an ultraviolet light on one surface of the near infrared light filtering substrate 11. Then Step S12 is performed, and the method involves forming a first multi-layer film 15 on the absorbing layer 13. Finally, step S13 is performed, and the method involves forming a second multi-layer film 17 on the other surface of the near infrared light filtering substrate 11. In one embodiment, the absorbing layer 13 is formed on the near infrared light filtering substrate 11 through a coating method. In one embodiment, the first multi-layer film 15 and the second multi-layer film 17 are separately formed on the absorbing layer 13 and the near infrared light filtering substrate 11 through an evaporation process. On the other hand, the first multi-layer film 15 located on the absorbing layer 13 and the second multi-layer film 17 located on the near infrared light filtering substrate 11 may also be manufactured through the evaporation process at the same time.

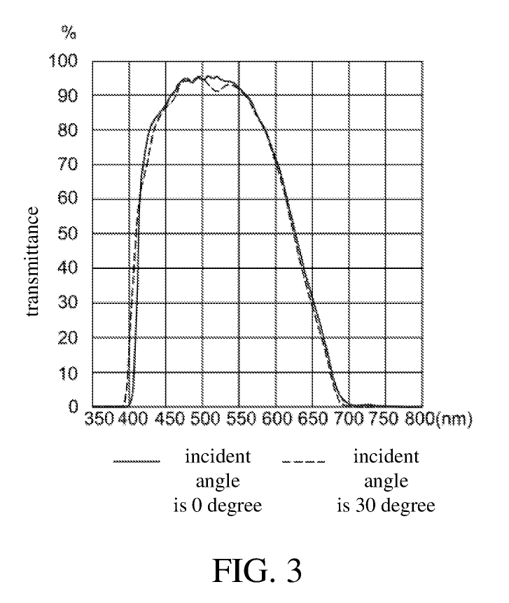

Please refer to FIG. 3, which is a schematic view of a spectral transmission curve of a filter 1 according to an embodiment of the present disclosure. As shown in FIG. 3, FIG. 3 shows a spectral transmission curve view of the filter 1 of the present disclosure, wherein a thickness of the filter at range between 0.2 to 0.4 mm and the incident angle of the incident light entering the filter 1 of the present disclosure is 0 degree and 30 degree. As can be seen from FIG. 3, a transmittance curve measured by the filter 1 of the present disclosure under the condition of the incident angle of the incident light entering the filter 1 between 0 degree and 30 degree and a transmittance curve measured by the filter 1 of the present disclosure under the condition of the incident angle of the incident light entering the filter 1 between 30 degrees are very similar. For the wavelength between 425 nm to 590 nm, the transmittance of the filter 1 of the present disclosure may be above 80%. The absorbing layer 13 of the filter 1 of the present disclosure absorbs the near infrared light and the ultraviolet light and greatly suppresses the transmittance of the wavelength range between 350 nm to 420 nm and 700 nm to 720 nm, thereby reducing the phenomenon of color shift.

As shown in the following Table 2, when the incident angle of the incident light entering the filter 1 is 0 degree, the average transmittance of the filter 1 of the present disclosure in the ultraviolet light region (the wavelength is 350 nm to 395 nm) is 0.01%. The average transmittance of the filter 1 of the present disclosure in the infrared light region (the wavelength is 735 nm to 1100 nm) is 0.03%. The average transmittance of the filter 1 of the present disclosure in the visible light region (the wavelength is 430 nm to 580 nm) is 91.6%. When the incident angle of the incident light entering the filter 1 is 30 degree, the average transmittance of the filter 1 of the present disclosure in the ultraviolet light region (the wavelength is 350 nm to 395 nm) is 0.09%. The average transmittance of the filter 1 of the present disclosure in the infrared light region (the wavelength is 735 nm to 1100 nm) is 0.04%. The average transmittance of the filter 1 of the present disclosure in the visible light region (the wavelength is 430 nm to 580 nm) is 90.3%. It can be seen that the filter 1 of the present disclosure may effectively shield the ultraviolet band and the infrared band, such that the visible may be effectively passed through.

TABLE 2

| | incident angle | incident angle |
|---|---|---|
| | is 0 degree | is 30 degrees |
| average transmittance with λ as 350 nm | 0.01 | 0.09 |
| to 395 nm (%) | | |
| average transmittance with λ as 735 nm | 0.03 | 0.04 |
| to 1100 nm (%) | | |
| average transmittance with λ as 430 nm | 91.6 | 90.3 |
| to 580 nm (%) | | |

As shown in Table 3, when the incident angle of the incident light entering the filter 1 is 0 degree and 30 degree, in the ultraviolet light region and a state of 50% transmittance of the filter 1 of the present disclosure, the light having the wavelength of about 412 nm and 410 nm may be capable of transmit the filter 1 of the present disclosure. In the infrared region and a state of 50% transmittance of the filter 1 of the present disclosure, the light having the wavelength of about 626 nm and 624 nm may be capable of transmit the filter 1 of the present disclosure. In other words, under the condition of 50% transmittance of the filter 1 of the present disclosure, when the incident angle of the incident light entering the filter 1 is 0 degree and 30 degree, the wavelength shift being capable of transmitting the filter 1 within the ultraviolet light region is 0 to 2 nm. When the incident angle of the incident light entering the filter 1 is 0 degree and 30 degree, the wavelength shift being capable of transmitting the filter 1 within the near infrared light region is 0 to 2 nm. It can be seen that when the incident angle of the incident light entering the filter 1 of the present disclosure is 0 degree and 30 degree, the phenomenon of color shift of the filter 1 of the present disclosure is not obvious.

TABLE 3

| | incident angle | incident angle |
|---|---|---|
| | is 0 degree | is 30 degrees |
| in ultraviolet light region and | 412 nm | 410 nm |
| wavelength with 50% transmittance | | |
| in infrared light region and | 626 nm | 624 nm |
| wavelength with 50% transmittance | | |

According to FIG. 3 and Tables 1 to 3, it can be clearly known that the filter 1 with absorbing layer 13 and the near infrared light filtering substrate 11 being capable of absorbing the infrared and the ultraviolet light may effectively shield the ultraviolet light and the near infrared light and may reduce the phenomenon of color shift generated by the filter 1 due to the incident light entering at different angles in the ultraviolet light region and the infrared light region.

As mentioned above, the present disclosure discloses a filter. The filter generates different spectrum properties according to the near infrared light absorbing dyes of the near infrared light filtering substrate and the absorbing layer, so as to adjust and control the spectrum pattern needed by the filter of the present disclosure, thereby reducing the phenomenon of color shift generated by the filter under the incident light entering the filter in different incident angles and maintaining the transmittance of the visible light passing the filter. Specifically, the filter provided by the present disclosure may greatly improve the transmittance for the visible light with wavelength between 600 nm to 700 nm, effectively absorb the near infrared light and the ultraviolet light, and reduce the transmittance of the near infrared light and the ultraviolet light.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the invention. Accordingly, such modifications are considered within the scope of the invention as limited solely by the appended claims.

What is claimed is:

1. A filter, comprising:
a near infrared light filtering substrate, having a near infrared light absorbing dye;
an absorbing layer, having a near infrared light absorbing dye and an ultraviolet light absorbing dye, and formed on one surface of the near infrared light filtering substrate;
a first multi-layer film, formed on the absorbing layer; and
a second multi-layer film, formed on the other surface of the near infrared light filtering substrate.

2. The filter as claimed in claim 1, wherein the material of the near infrared light filtering substrate comprises at least one of polycarbonate, polystyrene, propylene-styrene copolymer, polymethyl methacrylate, polyvinylchloride, low density polyethylene, ethylene-vinyl acetate and cyclic polyolefin resin.

3. The filter as claimed in claim 1, wherein a thickness of the absorbing layer is between 2.5 μm to 3.5 μm.

4. The filter as claimed in claim 1, wherein a thickness of the absorbing layer is 3 μm.

5. The filter as claimed in claim 1, wherein a thickness of the first multi-layer film and a thickness of the second multi-layer film are between 10 nm to 500 nm.

6. The filter as claimed in claim 1, wherein the first multi-layer film and the second multi-layer comprises TiO₂ and SiO₂.

7. The filter as claimed in claim 1, wherein the absorbing layer absorbs the light having the wavelength between 350 nm to 420 nm and 630 nm to 800 nm.

8. The filter as claimed in claim 1, wherein the first multi-layer film and the second first multi-layer film absorb the light having the wavelength between 700 nm to 1200 nm.

9. The filter as claimed in claim 1, wherein in an ultraviolet light region, a difference between a wavelength of the filter with an incident angle of 0 degree and transmittance of 50% and a wavelength of the filter with an incident angle of 30 degree and transmittance of 50% is less or equal to 2 nm.

10. The filter as claimed in claim 1, wherein in an infrared region, a difference between a wavelength of the filter with an incident angle of 0 degree and transmittance of 50% and a wavelength of the filter with an incident angle of 30 degree and transmittance of 50% is less or equal to 2 nm.

11. The filter as claimed in claim 1, wherein the ratio of mass concentration of the near infrared light absorbing dye of the near infrared light filtering substrate to mass concentration of the near infrared light absorbing dye of the absorbing layer is 1:0.03.

12. The filter as claimed in claim 1, wherein the material of the absorbing layer comprises polyester resin, acrylic resin, polycarbonate resin, polyamide resin, alkyd resin, epoxy resin or thermosetting acrylic resin.
